(19) United States
(12) Patent Application Publication
(10) Pub. No.: US 2012/0235112 A1
(43) Pub. Date: Sep. 20, 2012

(54) RESISTIVE SWITCHING MEMORY AND METHOD FOR MANUFACTURING THE SAME

(76) Inventors: Zongliang Huo, Beijing (CN); Ming Liu, Beijing (CN); Jing Liu, Beijing (CN)

(21) Appl. No.: 13/511,861

(22) PCT Filed: Jun. 30, 2011
(86) PCT No.: PCT/CN2011/076637

§ 371 Date: May 24, 2012

(30) Foreign Application Priority Data
Nov. 30, 2010 (CN) 201010574007.6

(51) Int. Cl. H01L 45/00; H01L 21/8239

(52) U.S. Cl. 257/4; 438/382; 257/E45.003; 257/E21.645; 257/E21.004

(57) ABSTRACT

The present disclosure relates to the microelectronics field, and particularly, to a resistive switching memory and a method for manufacturing the same. The memory may comprise a lower electrode, a resistive switching layer, and an upper electrode. The resistive switching layer may have carbon nano-tubes embedded therein. Growth of a conductive filament in the resistive switching layer can be facilitated and controlled under an externally applied bias by a local electric field enhancement effect of the carbon nano-tubes, so as to improve performances and stability of the device. The resistive switching memory according to the present disclosure can have a good resistive switching capability. Further, the operating voltage and the resistance value of the device can be well controlled by controlling the length and position of the carbon nano-tubes in the resistive switching layer.

### TECHNICAL FIELD

The present disclosure relates to the field of microelectronics and memories, and particularly, to a resistive switching memory and a method for manufacturing the same.

### BACKGROUND

Among nonvolatile memories currently on the market, flash memories are most popular. However, with continuous scaling of devices, the flash memories tend to present disadvantages, such as large operating voltage, slow operating speed, poor durability, and relatively short retention due to an excessively thin tunneling oxide layer. It is desirable that a nonvolatile memory can meet criteria such as low operating voltage, simple configuration, non-destructive reading, high operating speed, relatively long retention, small footprint, and good endurance.

Efforts have been directed to a variety of novel materials and devices to achieve the above objects. A significant number of those novel memory devices achieve storage by means of resistive switching. Especially, Resistive Random Access Memories (RRAMs) are mainly based on the property of changeable resistance of solid-state oxide thin film materials. FIG. 1 shows an example configuration of a RRAM. Specifically, the RRAM comprises an upper electrode, a resistive switching layer, and a lower layer stacked on top of each other. Under a proper bias voltage applied thereto, the thin film of the resistive switching layer may have a conductive filament or a break formed therein, as shown in FIG. 2, and thus may assume two different states of resistance value. Those two states of resistance value can be reversibly changed from one to the other under an externally applied electric field. As a result, storage of two states such as “0” and “1” is achieved.

The RRAMs have a potential to replace the currently popular flash memories at the 32 nm node and beyond, and thus become an important research subject on novel memory devices. At present, material systems for the RRAMs comprise complex oxides such as Pr₁₋ₓCaₓMnO₃, perovskite materials such as SrTiO₃ and SrZrO₃, and simple binary oxides of transition metals such as Cu, Ti, Ni, Ta, Hf, and Nb. As compared with the complex materials, the binary oxides of the transition metals are advantageous because they are simple in their configurations, easy to manufacture, and compatible with the existing CMOS processes.

However, a bottleneck that prevents the RRAM devices from practical applications is that the performance stability of the devices is hard to control and so far cannot meet the requirement of large scale integration. To further improve the performances and yield of the RRAM devices, conventionally nano-crystal particles are incorporated into the resistive switching material. The nano-crystal particles can cause a local field enhancement effect, by which it is possible to improve the performance uniformity and stability of the devices by controlling the size and distribution of the nano-crystal particles so as to control the growth of the conductive filament in the resistive switching layer, as shown in FIG. 3. This becomes an effective measure to put the resistive switching technique into practice. Incorporation of the nano-crystal particles into the resistive switching layer can be implemented by depositing a thin film of a nano-crystal material by means of, for example, CVD or PVD, and then performing a proper thermal treatment thereon to form nano-crystal particles.

However, with the continuous scaling of the devices, the above described solution is encountering severe challenges. Those are mainly caused by the fact that the size (5-15 nm) of the nano-crystal particles is unlikely to be further reduced, and also is unlikely to have a uniformity across a large area. When the feature size of the RRAM devices is scaled down to 15-20 nm, the nano-crystal particles have their size comparable to the devices. As a result, it is impossible to ensure a distribution or presence of the nano-crystal particles in various RRAM devices in an array. In other words, the nano-crystal particles cannot adjust the performances of the devices any more. Therefore, there is a need for an improved solution.

### SUMMARY

In view of the above problems in the prior art resistive switching memories, especially, the problem that they are insufficient in the resistive switching capability, the present disclosure aims to provide, among other things, a resistive switching memory and a method for manufacturing the same, which is easy to manufacture and low in cost, and can have a good resistive switching capability.

According to an embodiment, there is provided a resistive switching memory comprising a lower electrode, a resistive switching layer, and an upper electrode. The resistive switching layer may have carbon nano-tubes embedded therein. Growth of a conductive filament in the resistive switching layer can be facilitated and controlled under an externally applied bias by a local electric field enhancement effect of the carbon nano-tubes, so as to improve performances and stability of the device.

In the above configuration, the resistive switching layer may comprise a single layer of an individual resistive switching material, or a composite layer of a plurality of resistive switching materials stacked on each other. The resistive switching layer may comprise a complex oxide, a perovskite material, or a binary oxide of transition metal. The complex oxide may comprise Pr₁₋ₓCaₓMnO₃. The perovskite material may comprise SrTiO₃ or SrZrO₃. The binary oxide of transition metal may comprise HfO₂, CuO₂, TiO₂, or ZrO₂.

In the above configuration, the carbon nano-tubes can be embedded at any position in the resistive switching layer, including a position immediately adjacent to the upper electrode at an interface between the resistive switching layer and the upper electrode, a position immediately adjacent to the lower electrode at an interface between the resistive switching layer and the lower electrode, and any position inside the resistive switching layer.

In the above configuration, the upper or lower electrode may comprise a thin film of doped silicon, metal, metal nitride, or metal silicide. The lower electrode may comprise Ag, Au, Cu, W, Ti, Pt, TiN, WN, or TaN. The upper electrode may comprise Ag, Au, Cu, W, Ti, or Pt.

According to a further embodiment, there is provided a method for manufacturing a resistive switching memory, comprising: forming a lower electrode on a substrate; depositing a catalyst agent for growth of carbon nano-tubes on a surface of the lower electrode; growing an isolation dielectric layer on a surface of the catalyst agent; etching the isolation dielectric layer to form a through-hole therein; growing the carbon nano-tubes on the etched isolation dielectric layer; depositing a resistive switching layer on the carbon nano-tubes; planarizing the deposited resistive switching layer; and depositing an upper electrode on the planarized resistive switching layer.

In the above configuration, forming the lower electrode on the substrate may be achieved by means of electron beam evaporation.

In the above configuration, the catalyst agent may comprise Ni, Fe, or Co.

In the above configuration, growing the isolation dielectric layer on the surface of the catalyst agent may be achieved by means of CVD, evaporation, or sputtering. The isolation dielectric layer may comprise SiO₂, Si₃N₄, or BPSG.

In the above configuration, growing the carbon nano-tubes on the etched isolation dielectric layer may be achieved by means of CVD or chemical spin coating.

In the above configuration, depositing the resistive switching layer on the carbon nano-tubes may be achieved by means of electron beam evaporation.

In the above configuration, planarizing the deposited resistive switching layer may be achieved by means of Chemical Mechanical Polishing.

In the above configuration, depositing the upper electrode on the planarized resistive switching layer may be achieved by means of electron beam evaporation.

According to a still further embodiment, there is provided a method for manufacturing a resistive switching memory, comprising: forming a lower electrode on a substrate; growing an isolation dielectric layer on a surface of the lower electrode; etching the isolation dielectric layer to form a through-hole therein, wherein the etching is stopped on the surface of the lower electrode; depositing a resistive switching material in the through-hole; depositing a catalyst agent for growth of carbon nano-tubes on the resistive switching material; growing the carbon nano-tubes on the catalyst agent; further depositing the resistive switching material on the carbon nano-tubes to fill up the through-hole; planarizing the deposited resistive switching layer; and depositing an upper electrode on the planarized resistive switching layer.

In the above configuration, in depositing the resistive switching material in the through-hole, the deposited resistive switching material does not fill up the through-hole, and a height of the resistive switching material deposited in the through-hole determines a position where the nano-tubes are positioned in the resistive switching layer.

In the above configuration, the catalyst agent may comprise Ni, Fe, or Co. Growing the carbon nano-tubes on the catalyst agent may be achieved by means of CVD or chemical spin coating.

According to a yet further embodiment, there is provided a method for manufacturing a resistive switching memory, comprising: forming a lower electrode on a substrate; growing an isolation dielectric layer on a surface of the lower electrode; etching the isolation dielectric layer to form a through-hole therein, wherein the etching is stopped on the surface of the lower electrode; depositing a resistive switching material in the through-hole to fill up the through-hole; etching the resistive switching material deposited in the through-hole; depositing a catalyst agent for growth of carbon nano-tubes on the remaining resistive switching material; growing the carbon nano-tubes on the catalyst agent; and depositing an upper electrode on the carbon nano-tubes.

In the above configuration, the catalyst agent may comprise Ni, Fe, or Co. Growing the carbon nano-tubes on the catalyst agent may be achieved by means of CVD or chemical spin coating.

The embodiments of the present disclosure can present at least some of the following advantages.

According to some embodiments of the present disclosure, the carbon nano-tubes are adopted instead of nano-crystal particles to improve performances of RRAM devices. The carbon nano-tubes are very small in size (having a diameter of about 0.5 nm), and the manufacture process thereof tends to achieve a good uniform distribution among small-sized devices. Therefore, the RRAM devices with the resistive switching memory according to the embodiments of the present disclosure can have a good resistive switching capability.

According to some embodiments of the present disclosure, the operating voltage and the resistance value of the device can be well controlled by controlling the length and position of the carbon nano-tubes in the resistive switching layer.

According to some embodiments of the present disclosure, adjustment of the operating voltage of the device can be achieved by controlling the length of the carbon nano-tubes, so as to improve the stability of the device.

According to some embodiments of the present disclosure, the resistive switching memory is easy to manufacture and low in cost, and thus is advantageous in popularization and application thereof.

### BRIEF DESCRIPTION OF THE DRAWINGS

FIG. 1 is a schematic view showing a basic configuration of a nonvolatile resistive switching memory in the prior art.

FIG. 2 is a schematic view showing a basic configuration and a storage principle of a RRAM device in the prior art.

FIG. 3 is a schematic view showing the prior art technique where a field enhancement effect of nano-crystal particles is adopted.

FIG. 4 is a schematic view showing a resistive switching memory with a good resistive switching capability according to an embodiment of the present disclosure.

FIGS. 5-1 to 5-7 show a flow of manufacturing a resistive switching memory with a good resistive switching capability according to an embodiment of the present disclosure.

FIG. 6 is a schematic view showing a 1D1R memory array implemented on a RRAM prototype according to an embodiment of the present disclosure.

### DETAILED DESCRIPTION

The present disclosure will be more apparent from the following detailed descriptions in conjunction with illustrative embodiments with reference to the attached drawings.

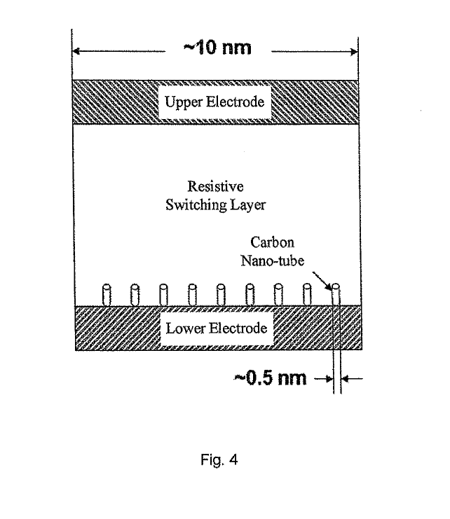

FIG. 4 is a schematic view showing a resistive switching memory with a good resistive switching capability according to an embodiment of the present disclosure. As shown in FIG. 4, the resistive switching memory may comprise a lower electrode, a resistive switching layer, and an upper layer. The resistive switching layer may have carbon nano-tubes embedded therein. It is possible to facilitate and control growth of a conductive filament in the resistive switching layer under an externally applied bias by a local electric field enhancement effect of the carbon nano-tubes, so as to improve performances and stability of the device.

In the resistive switching memory according to the embodiment of the present disclosure, the carbon nano-tubes are adopted instead of nano-crystal particles to improve the performances of RRAM devices. The carbon nano-tubes are very small in size (having a diameter of about 0.5 nm), and the manufacture process thereof tends to achieve a good uniform distribution among small-sized devices. Therefore, the RRAM devices with the resistive switching memory according to the embodiment of the present disclosure can have a good resistive switching capability.

According to an embodiment, the resistive switching layer may comprise a single layer of an individual resistive switching material, or a composite layer of a plurality of resistive switching materials stacked on each other. The carbon nano-tubes can be embedded at any position in the resistive switching layer, such as a position immediately adjacent to the upper electrode (i.e., an interface between the resistive switching layer and the upper electrode), a position immediately adjacent to the lower electrode (i.e., an interface between the resistive switching layer and the lower electrode), and any position inside the resistive switching layer. The carbon nano-tubes can be embedded into the resistive switching layer as follows. Firstly, a portion of the resistive switching layer is grown. Then, a catalyst agent required for deposition of the carbon nano-tubes is grown on the portion of the resistive switching layer. Next, the carbon nano-tubes are grown on a surface of the catalyst agent. And finally, a remaining portion of the resistive switching layer is grown on the carbon nano-tubes. As a result, the resistive switching layer embedded with the carbon nano-tubes is achieved.

Further, the length and density of the carbon nano-tubes can be controlled by adjusting the process. The control of the length of the carbon nano-tubes can achieve adjustment of an operating voltage and a resistance value of the device. More specifically, it is possible to reduce the operating voltage and the resistance value of the device by increasing the length of the carbon nano-tubes. As a result, a proper operating voltage and a proper magnitude of the resistance value can be achieved by adjusting the length of the carbon nano-tubes. The density of the carbon nano-tubes can depend, at least partially, on a density of the catalyst agent, and the length of the carbon nano-tubes can depend, at least partially, on the growing time of the carbon nano-tubes.

According to an embodiment, the resistive switching layer may comprise a complex oxide, a perovskite material, a binary oxide of transition metal, and the like. The complex oxide may comprise Pr₁₋ₓCaₓMnO₃, the perovskite material may comprise SrTiO₃ or SrZrO₃, and the binary oxide of transition metal may comprise HfO₂, CuO₂, TiO₃, or ZrO₂.

According to an embodiment, the upper or lower electrode may comprise a thin film of doped silicon, metal, metal nitride, or metal silicide. In a case where the upper and lower electrodes both comprise metal, the lower electrode may comprise Ag, Au, Cu, W, Ti, Pt, TIN, WN, or TaN, and the upper electrode may comprise Ag, Au, Cu, W, Ti, or Pt.

According to a further embodiment of the present disclosure, there is provided a method for manufacturing a resistive switching memory with a good resistive switching capability. The method may comprise steps of:
forming a lower electrode on a substrate;
depositing a catalyst agent for growth of carbon nano-tubes on a surface of the lower electrode;
growing an isolation dielectric layer on a surface of the catalyst agent;
etching the isolation dielectric layer to form a through-hole therein;
growing the carbon nano-tubes in the through-hole formed in the isolation dielectric layer;
depositing a resistive switching layer in a form of thin film on the carbon nano-tubes;
planarizing the deposited resistive switching layer; and
depositing an upper electrode on the planarized resistive switching layer.

According to some embodiments, the lower electrode may be formed on the substrate and the upper electrode may be formed on the planarized resistive switching layer by means of electron beam evaporation. The catalyst agent for growth of the carbon nano-tubes may comprise a thin layer of metal such as Ni, Fe, and Co, and may be formed on the surface of the lower electrode by means of electron beam evaporation. The isolation dielectric layer may be formed on the surface of the catalyst agent by means of CVD, evaporation, or sputtering, and may comprise SiO₂, Si₃N₄, or BPSG. The carbon nano-tubes may be grown in the through-hole formed in the isolation dielectric layer by means of CVD or chemical spin coating.

In a case where the carbon nano-tubes are grown by means of CVD, it is possible to achieve the carbon nano-tubes in different densities by adjusting conditions adopted in CVD, such as temperature, pressure, and power. Further, it is possible to adjust the length of the carbon nano-tubes by controlling the CVD growing time. In a case where the carbon nano-tubes are grown by means of chemical spin coating, it is possible to achieve the carbon nano-tubes in different densities by selecting a mole number for a sol solution for spin coating and controlling a rotational speed of a centrifuge for spin coating.

The resistive switching layer may be deposited on the carbon nano-tubes by means of electron beam evaporation. The deposited resistive switching layer may be planarized by means of Chemical Mechanical Polishing (CMP).

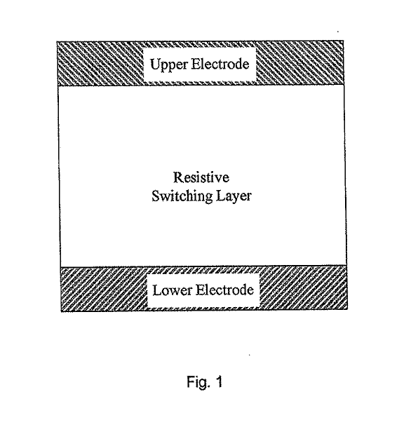

According to an embodiment, the lower electrode may comprise Au, the resistive switching layer may comprise ZrO₂, and the upper electrode may comprise Pt. In this case, the device can be manufactured as follows, as shown in FIGS. 5-1 to 5-7. Specifically, a thin film of Au may be deposited on a substrate by means of electron beam evaporation, to serve as a lower metal electrode for the device. A thin film of Co may be deposited on the thin film of Au, to serve as a catalyst agent for growth of carbon nano-tubes. An isolation dielectric layer of SiO₂ may be deposited by means of CVD, and then etched to form a through-hole therein. Carbon nano-tubes may be grown in the through-hole by means of CVD. A resistive switching layer of ZrO₂ may be deposited on the carbon nano-tubes by means of electron beam evaporation, and then planarized by means of CMP. Finally, an upper electrode of Ti and Pt may be deposited on the resistive switching layer of ZrO₂ by means of electron beam evaporation, resulting in the device.

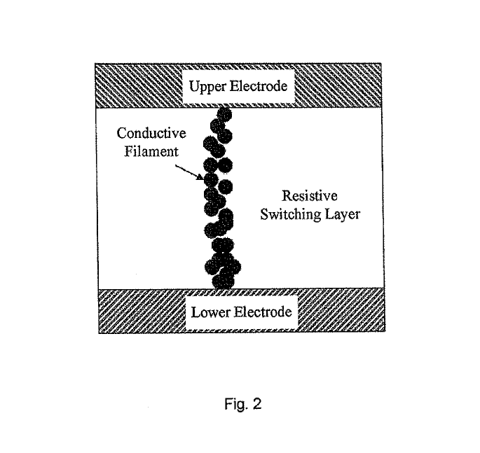

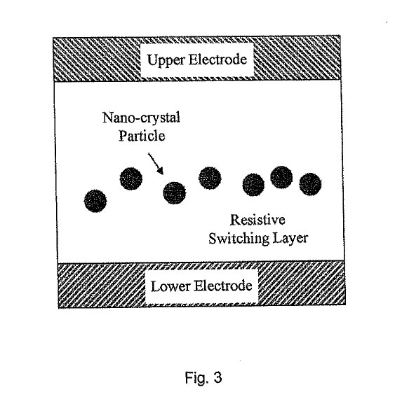

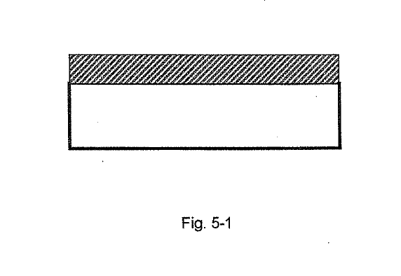

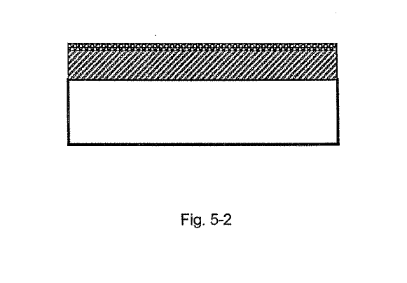

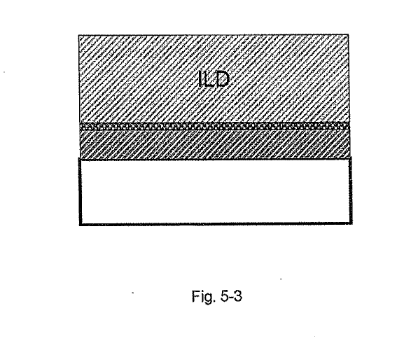

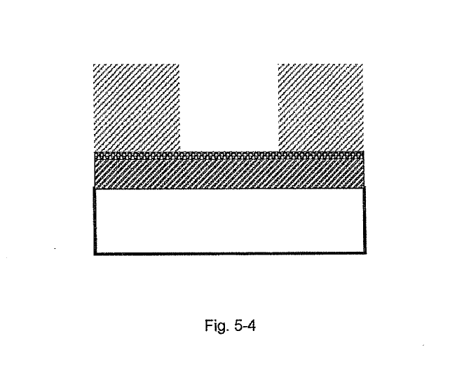

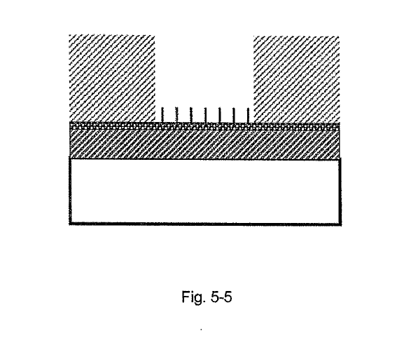

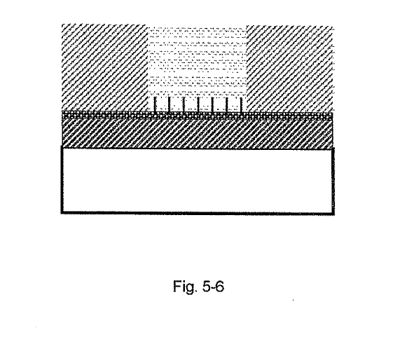

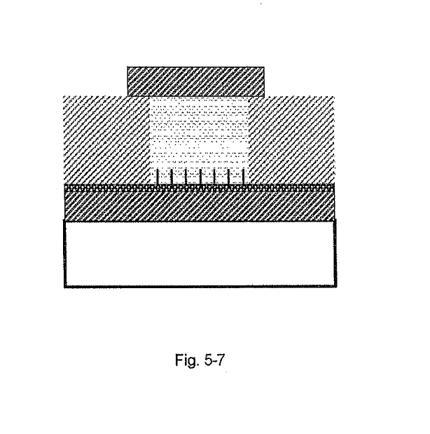

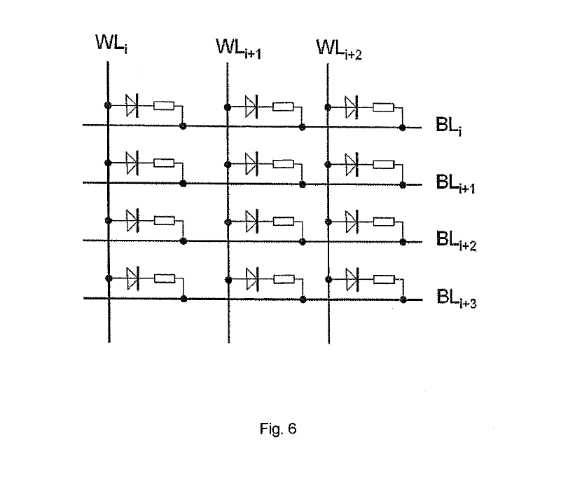

FIGS. 5-1 to 5-7 show a flow of manufacturing a resistive switching memory with a good resistive switching capability according to an embodiment of the present disclosure. FIG. 5-1 is a schematic view showing an operation of forming a lower electrode of Au on a substrate. FIG. 5-2 is a schematic view showing an operation of depositing a catalyst agent of Ni for growth of carbon nano-tubes on a surface of the lower electrode of Au. FIG. 5-3 is a schematic view showing an operation of depositing an isolation dielectric layer of SiO₂ on a surface of the catalyst agent of Ni by means of CVD. FIG. 5-4 is a schematic view showing an operation of etching the isolation dielectric layer of SiO₂ to form a through-hole therein, wherein the etching is stopped on the surface of the catalyst agent of Ni. FIG. 5-5 is a schematic view showing an operation of forming the carbon nano-tubes on the surface of the catalyst agent of Ni exposed by the through-hole. FIG. 5-6 is a schematic view showing an operation of depositing a resistive switching layer of ZrO₂ on the carbon nano-tubes by means of electron beam evaporation. FIG. 5-7 is a schematic view showing an operation of planarization and an operation of depositing an upper electrode of Ti and Pt by means of electron beam evaporation. By the operations shown in FIGS. 5-1 to 5-7, the resistive switching memory with a good resistive switching capability is achieved.

In the above embodiments, the carbon nano-tubes are embedded at an interface between the resistive switching layer and the lower electrode (i.e., a position immediately adjacent to the lower electrode). Certainly, the carbon nano-tubes can be embedded at any position in the resistive switching layer, e.g., a position immediately adjacent to the upper electrode (i.e., an interface between the resistive switching layer and the upper electrode), and any position inside the resistive switching layer.

A device where carbon nano-tubes are embedded at any position inside a resistive switching layer can be manufactured as follows. Specifically, a lower electrode may be formed on a substrate. An isolation dielectric layer may be grown on a surface of the lower electrode, and then etched to form a through-hole therein, wherein the etching can be stopped on the surface of the lower electrode. A resistive switching material may be deposited into the through-hole, without completely filling the through-hole up with the resistive switching material. In this case, a height of the resistive switching material deposited in the through-hole determines a position where nano-tubes are positioned in a resistive switching layer. Then, a catalyst agent for growth of nano-tubes may be deposited on the resistive switching material, and the carbon nano-tubes may be grown on the catalyst agent. Next, the resistive switching material may be further deposited on the carbon nano-tubes to fill up the through-hole. The deposited resistive switching film can be planarized, and an upper electrode may be deposited on the planarized resistive switching film. The catalyst agent may comprise Ni, Fe or Co, and the carbon nano-tubes may be grown on the catalyst agent by means of CVD or chemical sin coating.

A device where carbon nano-tubes are embedded at any position immediately adjacent to an upper electrode can be manufactured as follows. Specifically, a lower electrode may be formed on a substrate. An isolation dielectric layer may be grown on a surface of the lower electrode, and then etched to form a through-hole therein, wherein the etching can be stopped on the surface of the lower electrode. A resistive switching material may be deposited into the through-hole to fill the through-hole up, and then etched to a depth by which the requirement of growing carbon nano-tubes on the remaining resistive switching material can be satisfied. Next, a catalyst agent for growth of the carbon nano-tubes may be deposited on the remaining resistive switching material, and the carbon nano-tubes may be grown on the catalyst agent. An upper electrode may be deposited on the carbon nano-tubes. The catalyst agent may comprise Ni, Fe or Co, and the carbon nano-tubes may be grown on the catalyst agent by means of CVD or chemical spin coating.

According to embodiments of the present disclosure, the nonvolatile memory device can have a good resistive switching capability. Further, the operating voltage and the resistance value of the device can be well controlled by controlling the length and position of the carbon nano-tubes in the resistive switching layer. Furthermore, the nonvolatile memory device according to the embodiments is easy to manufacture, low in cost, and well compatible with the conventional silicon based planar CMOS processes, and thus is ready for industrial applications and popularization.

From the foregoing, it will be appreciated that specific embodiments of the disclosure have been described herein for purposes of illustration, but that various modifications may be made without deviating from the disclosure. In addition, many of the elements of one embodiment may be combined with other embodiments in addition to or in lieu of the elements of the other embodiments. Accordingly, the technology is not limited except as by the appended claims.

I/We claim:

1. A resistive switching memory comprising a lower electrode, a resistive switching layer, and an upper electrode,
wherein the resistive switching layer has carbon nano-tubes embedded therein, and
wherein growth of a conductive filament in the resistive switching layer can be facilitated and controlled under an externally applied bias by a local electric field enhancement effect of the carbon nano-tubes, so as to improve performances and stability of the device.

2. The resistive switching memory according to claim 1, wherein the resistive switching layer comprises a single layer of an individual resistive switching material or a composite layer of a plurality of resistive switching materials stacked on each other.

3. The resistive switching memory according to claim 2, wherein the resistive switching layer comprises a complex oxide, a perovskite material, or a binary oxide of transition metal.

4. The resistive switching memory according to claim 3, wherein the complex oxide comprises Pr₁₋ₓCaₓMnO₃.

5. The resistive switching memory according to claim 3, wherein the perovskite material comprises SrTiO₃ or SrZrO₃.

6. The resistive switching memory according to claim 3, wherein the binary oxide of transition metal comprises HfO₂, CuO₂, TiO₂, or ZrO₂.

7. The resistive switching memory according to claim 1, wherein the carbon nano-tubes can be embedded at any position in the resistive switching layer, including a position immediately adjacent to the upper electrode at an interface between the resistive switching layer and the upper electrode, a position immediately adjacent to the lower electrode at an interface between the resistive switching layer and the lower electrode, and any position inside the resistive switching layer.

8. The resistive switching memory according to claim 1, wherein the upper or lower electrode comprises a thin film of doped silicon, metal, metal nitride, or metal silicide.

9. The resistive switching memory according to claim 8, wherein the lower electrode comprises Ag, Au, Cu, W, Ti, Pt, TiN, WN, or TaN.

10. The resistive switching memory according to claim 8, wherein the upper electrode comprises Ag, Au, Cu, W, Ti, or Pt.

11. A method for manufacturing a resistive switching memory, comprising:
forming a lower electrode on a substrate;
depositing a catalyst agent for growth of carbon nano-tubes on a surface of the lower electrode;
growing an isolation dielectric layer on a surface of the catalyst agent;
etching the isolation dielectric layer to form a through-hole therein;
growing the carbon nano-tubes on the etched isolation dielectric layer;
depositing a resistive switching layer on the carbon nano-tubes;
planarizing the deposited resistive switching layer; and
depositing an upper electrode on the planarized resistive switching layer.

12. The method according to claim 11, wherein forming the lower electrode on the substrate comprises forming the lower electrode on the substrate by means of electron beam evaporation.

13. The method according to claim 11, wherein the catalyst agent comprises Ni, Fe, or Co.

14. The method according to claim 11, wherein growing the isolation dielectric layer on the surface of the catalyst agent comprises growing the isolation dielectric layer on the surface of the catalyst agent by means of CVD, evaporation, or sputtering, and wherein the isolation dielectric layer comprises SiO₂, Si₃N₄, or BPSG.

15. The method according to claim 11, wherein growing the carbon nano-tubes on the etched isolation dielectric layer comprises growing the carbon nano-tubes on the etched isolation dielectric layer by means of CVD or chemical spin coating.

16. The method according to claim 11, wherein depositing the resistive switching layer on the carbon nano-tubes comprises depositing the resistive switching layer on the carbon nano-tubes by means of electron beam evaporation.

17. The method according to claim 11, wherein planarizing the deposited resistive switching layer comprises planarizing the deposited resistive switching layer by means of Chemical Mechanical Polishing.

18. The method according to claim 11, wherein depositing the upper electrode on the planarized resistive switching layer comprises depositing the upper electrode on the planarized resistive switching layer by means of electron beam evaporation.

19. A method for manufacturing a resistive switching memory, comprising:
forming a lower electrode on a substrate;
growing an isolation dielectric layer on a surface of the lower electrode;
etching the isolation dielectric layer to form a through-hole therein, wherein the etching is stopped on the surface of the lower electrode;
depositing a resistive switching material in the through-hole;
depositing a catalyst agent for growth of carbon nano-tubes on the resistive switching material;
growing the carbon nano-tubes on the catalyst agent;
further depositing the resistive switching material on the carbon nano-tubes to fill up the through-hole;
planarizing the deposited resistive switching layer; and
depositing an upper electrode on the planarized resistive switching layer.

20. The method according to claim 19, wherein depositing the resistive switching material in the through-hole comprises depositing the resistive switching material in the through-hole, without completely filling the through-hole up with the resistive switching material, wherein a height of the resistive switching material deposited in the through-hole determines a position where the nano-tubes are positioned in the resistive switching layer.

21. The method according to claim 19, wherein the catalyst agent comprises Ni, Fe, or Co, and growing the carbon nano-tubes on the catalyst agent comprises growing the carbon nano-tubes on the catalyst agent by means of CVD or chemical spin coating.

22. A method for manufacturing a resistive switching memory, comprising:
forming a lower electrode on a substrate;
growing an isolation dielectric layer on a surface of the lower electrode;
etching the isolation dielectric layer to form a through-hole therein, wherein the etching is stopped on the surface of the lower electrode;
depositing a resistive switching material in the through-hole to fill up the through-hole;
etching the resistive switching material deposited in the through-hole;
depositing a catalyst agent for growth of carbon nano-tubes on the remaining resistive switching material;
growing the carbon nano-tubes on the catalyst agent; and
depositing an upper electrode on the carbon nano-tubes.

23. The method according to claim 22, wherein the catalyst agent comprises Ni, Fe, or Co, and growing the carbon nano-tubes on the catalyst agent comprises growing the carbon nano-tubes on the catalyst agent by means of CVD or chemical spin coating.
